(19) United States
(12) Patent Application Publication
(10) Pub. No.: US 2012/0299157 A1
(43) Pub. Date: Nov. 29, 2012

(54) SEMICONDUCTOR PROCESS AND FABRICATED STRUCTURE THEREOF

(76) Inventors: Teng-Chun Hsuan, Tainan City (TW); Ted Ming-Lang Guo, Tainan City (TW); Chin-Cheng Chien, Tainan City (TW); Shu-Yen Chan, Changhua County (TW)

(21) Appl. No.: 13/115,125

(22) Filed: May 25, 2011

(51) Int. Cl. H01L 29/02; H01L 21/28

(52) U.S. Cl. 257/618; 438/585; 257/E21.19; 257/E29.002

(57) ABSTRACT

A semiconductor process includes the following steps. A substrate is provided, which includes an isolation structure and an oxide layer. The isolation structure divides the substrate into a first region and a second region. The oxide layer is located on the surface of the first region and the second region. A dry cleaning process is performed to remove the oxide layer. A dielectric layer is formed on the first region and the second region. A wet etching process is performed to remove at least one of the dielectric layers located on the first region and the second region. A semiconductor structure is fabricated by the above semiconductor process.

### BACKGROUND OF THE INVENTION

1. Field of the Invention

The present invention relates generally to a semiconductor process and fabricated structure thereof, and more specifically, to a semiconductor process and fabricated structure thereof applying a dry etching process to etch oxide layers.

2. Description of the Prior Art

A conventional Local Oxidation of Silicon (LOCOS) isolation method is usually replaced by a method that forms a shallow trench isolation structure in circuit processes that are lower than 250 nm, because of the bird's beak effect and the non-flatness of the surface. Although the shallow trench isolation structure can enhance component integration, it also gives rise to many problems that need to be solved in order to prevent electrical properties and the isolation performance of components from being degraded.

When the pad oxide layer or nitride layer is removed and wet treatment steps are performed during the shallow trench isolation structure forming process, the border of the shallow trench isolation structure is easy to be over-etched, which results in a divot being formed. FIG. 1 schematically depicts a cross-sectional view of a conventional shallow trench isolation structure. As shown in FIG. 1, a shallow trench isolation structure 120 is formed between the substrate 110. The edge of the top of the shallow trench isolation structure 120 will form divots D1 and D2 due to over-etching.

As the gate structure crosses the edge of the shallow trench isolation structure 120, the conductive body of the gate structure located on the edge of the shallow trench isolation structure 120 collapses into the divots D1 and D2, increasing local electrical fields and inducing transistor characteristics at the edge of components too early. This causes the hump phenomenon in the sub-threshold region of log Id-Vg. Furthermore, as the divots D1 and D2 enlarge and connect together such that they reduce the height of the shallow trench isolation structure 120, the gate structure that crosses the edge of the shallow trench isolation structure 120 will be shorted. This phenomenon becomes more obvious when the size of the semiconductor devices shrinks and the channel width decreases, resulting in a reduction of the threshold voltage (Vth) of the device.

### SUMMARY OF THE INVENTION

The present invention provides a semiconductor process and fabricated structure thereof to solve the above-mentioned problems.

The present invention provides a semiconductor process. A substrate is provided, which includes an isolation structure and an oxide layer. The isolation structure divides the substrate into a first region and a second region. The oxide layer is located on the surface of the first region and the second region. A dry cleaning process is performed to remove the oxide layer. A dielectric layer is formed on the first region and the second region. A wet etching process is performed to remove at least one of the dielectric layers located on the first region and the second region.

The present invention provides a semiconductor structure including a substrate, at least an isolation structure, and a dielectric layer. The isolation structure is located on the substrate, wherein the isolation structure has a trapezoid-shaped profile top protruding from the substrate, wherein the top width of the trapezoid-shaped profile top is 40% longer than the bottom width of the trapezoid-shaped profile top and the substrate next to the sides of the trapezoid-shaped profile top comprises a downward dent. The dielectric layer is located on the substrate and exposes the isolation structure.

According to the above, the present invention provides a semiconductor process and fabricated structure thereof, which removes the oxide layers by a dry cleaning process. Therefore, the semiconductor structure formed by the present invention has a smooth top profile with regards to the isolation structure. This means the semiconductor process of the present invention can reduce the size of the downward dent on the substrate and increase the top width/bottom width ratio of the top of the isolation structure. For instance, the top width of the top of the semiconductor structure is 40% larger than the bottom width. In this way, the present invention can solve the prior art problems of electrical field concentration or short-circuiting caused by the divots and downshifting of the height of the semiconductor structure top.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a conventional shallow trench isolation structure.

FIGS. 2-8 schematically depict a cross-sectional view of a semiconductor process according to one embodiment of the present invention.

FIG. 9 schematically depicts a cross-sectional view of a semiconductor process seen by Transmission Electron Microscopy (TEM) according to one embodiment of the present invention.

FIG. 10 schematically depicts a cross-sectional view of a semiconductor structure seen by Transmission Electron Microscopy (TEM) according to one embodiment of the present invention.

### DETAILED DESCRIPTION

FIGS. 2-8 schematically depict a cross-sectional view of a semiconductor process according to one embodiment of the present invention. Please refer to FIGS. 2-8. As shown in FIG. 2, a pad oxide layer 220 and a nitride layer 230 are sequentially formed on a substrate 210. Then, a lithography process is performed to form a photoresist layer 240 and define an insulating area A. The substrate 210 may be a semiconductor substrate such as a silicon substrate, a silicon-containing substrate, or a silicon-on-insulator (SOI) substrate. In this embodiment, the substrate 210 is a silicon substrate, the pad oxide layer 220 is a silicon dioxide layer, and the nitride layer 230 is a silicon nitride layer.

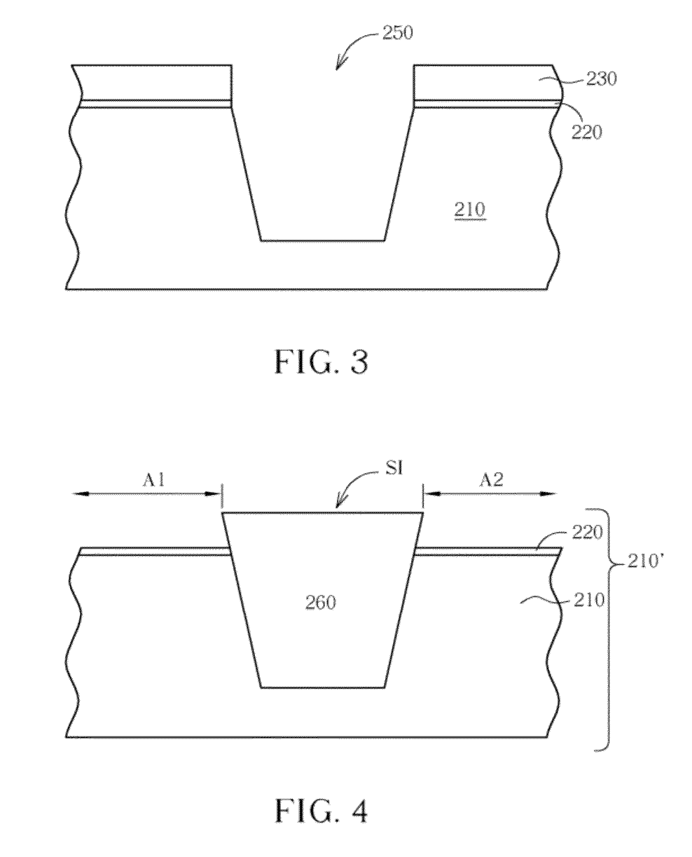

As shown in FIG. 3, the nitride layer 230 and the pad oxide layer 220 are patterned and the substrate 210 is etched to form a trench 250 by using the photoresist layer 240 as a mask for etching once or a plurality of times. The depth of the trench 250 is between 300 nm and 700 nm. A liner (not shown) is selectively formed on the inner sides of the trench 250 to eliminate damage caused during etching, wherein the liner may be an oxide layer, and it maybe formed by methods such as a thermal oxidation method, etc.

As shown in FIG. 4, an isolation structure 260 is filled in the trench 250 by methods such as chemical vapor deposition (CVD) or high aspect ratio process (HARP), etc. Then, the excess material of the isolation structure 260 is removed by applying chemical-mechanical polishing (CMP) and using the nitride layer 230 as a polish stop layer, thereby forming a flat surface S1 of the isolation structure 260 by trimming until the top surface of the nitride layer 230. The nitride layer 230 is then removed by using hot phosphoric acid (for example) for enabling the following processes to be performed. In this way, the isolation structure 260 protruding from the substrate 210 and the pad oxide layer 220 is formed. In other embodiments the isolation structure 260 may be a field oxide layer, but it is not limited thereto.

As shown in FIG. 4, a substrate 210′ of the present invention is formed, including an isolation structure 260 and a pad oxide layer 220. The isolation structure 260 divides the substrate 210′ into a plurality of active regions, such as a first region A1 and a second region A2. The pad oxide layer 220 is located on the surface of the first region A1 and the second region A2.

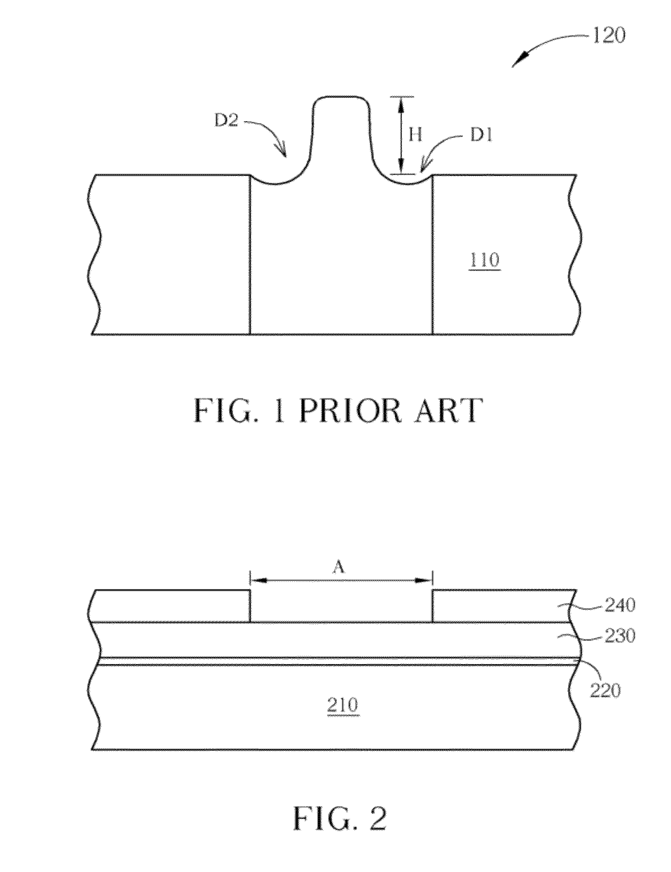

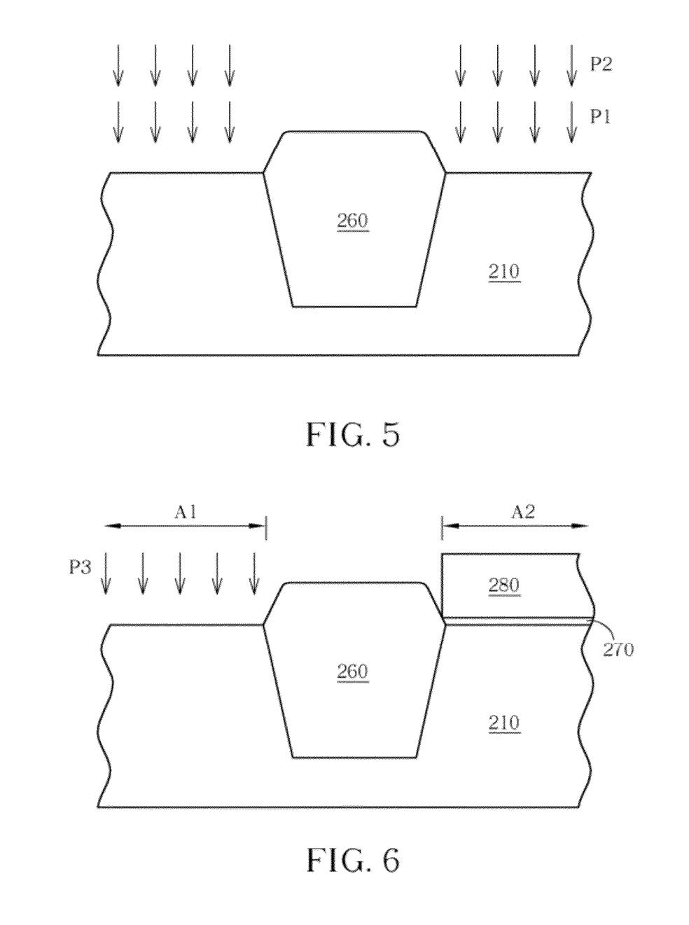

As shown in FIG. 5, a dry cleaning process P1 is performed to remove the pad oxide layer 220. The pad oxide layer 220 is etched by a wet etching process in conventional semiconductor processes. The material of the pad oxide layer 220 is similar to the isolation structure 260; both of them may be composed of oxides, for example. The wet etching process is an isotropic etching process, such that the etching selective ratio of the wet etching process for the pad oxide layer 220 and the isolation structure 260 is bad, causing a portion of the isolation structure 260 to also be etched while the pad oxide layer 220 is etched. This leads to divots being generated on the isolation structure 260 (shown as D1 and D2 in FIG. 1), causing the problems of the prior art to occur. Compared to the prior art, the present invention applies the dry cleaning process P1 instead, which is an anisotropic etching process, so that the dry cleaning process P1 has a better etching selective ratio for the pad oxide layer 220 and the isolation structure 260 than the prior art. Furthermore, the parameters of the dry cleaning process P1 are more flexible than the wet etching process, and therefore the desired shape of the isolation structure 260 can be attained precisely. In this embodiment, the dry cleaning process P1 is a SiCoNi dry cleaning process, but the dry cleaning process P1 may also include a nitrogen trifluoride and ammonia containing dry cleaning process, and is not limited thereto. When using the SiCoNi dry cleaning process as an example, the changing of the chemical ingredients may be shown as follows:

etchant generated: NF₃+NH₃→NH₄F+NH₄F.HF
etching: NH₄F+NH₄F .HF+SiO₂→(NH₄)₂SiF₆(ₛ)+H₂O (the wafer temperature during etching >35° C.)
annealing: (NH₄)₂SiF₆(ₛ) →SiF₄(_{g})+NH₃(_{g})+HF(_{g}) (the wafer temperature during annealing >100° C.)

After the dry cleaning process P1 is performed, a wet cleaning process P2 is selectively performed for further removing the pad oxide layer 220. The reason for this second process is: some fluoride ions may remain after the SiCoNi dry cleaning process is performed, so that the wet cleaning process P2 is further performed to remove the remained fluoride ions and impurities such as native oxide on the substrate 210′. In this embodiment, the wet cleaning process P2 is a hydrofluoric acid-containing cleaning process, and the processing time of the wet cleaning process P2 is preferably 15 seconds. Moreover, after the wet cleaning process P2 is performed, a standard clean 1 (SC1) and a standard clean 2(SC2) may be selectively performed. In this way, the fluoride ions and impurities can be removed without degrading the shape of the isolation structure 260.

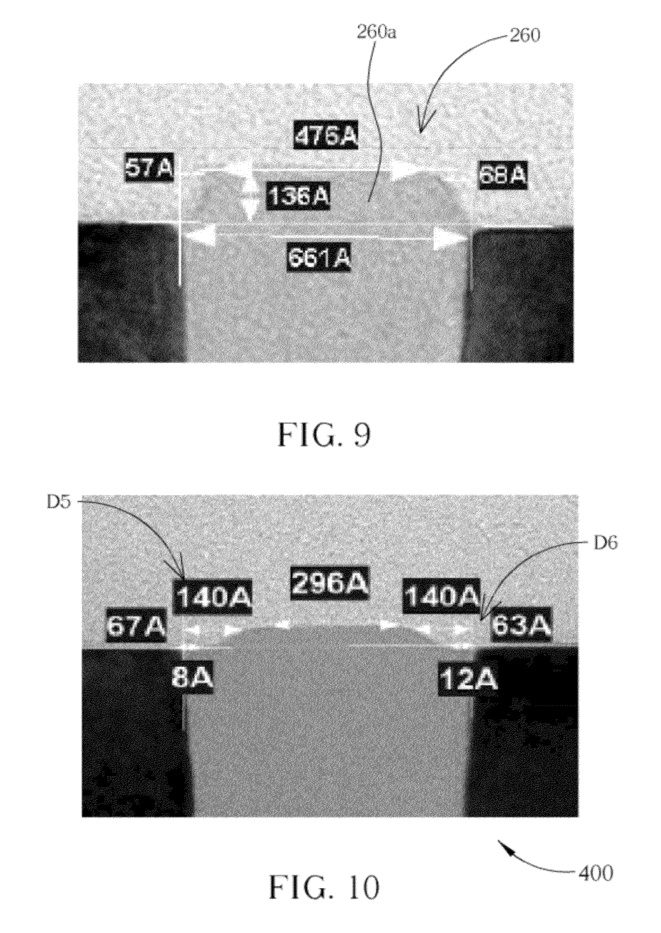

FIG. 9 schematically depicts a cross-sectional view of a semiconductor process seen by Transmission Electron Microscopy (TEM) after the dry cleaning process P1 is performed, according to one embodiment of the present invention. As shown in FIG. 9, the isolation structure 260 does not have obvious divots (shown as D1 and D2 of FIG. 1), and the isolation structure 260 having a top 260a protruding from the substrate 210 substantially has a trapezoid-shaped profile.

As shown in FIG. 6, general semiconductor processes may be sequentially performed, such as forming a dielectric layer 270 on the first region A1 and the second region A2. In this embodiment, the thickness of the dielectric layer expected to be formed on the first region A1 is thinner than the thickness of the dielectric layer expected to be formed on the second region A2 for applying the dielectric layer on the first region A1 to high voltage components and applying the dielectric layer on the second region A2 to low voltage components. This means the dielectric layer 270 on the first region A1 maybe removed first and a thinner dielectric layer is then formed. A patterned photoresist 280 is first formed under the dielectric layer 270 to protect it, and the dielectric layer 270 on the first region A1 is etched. The forming process of the dielectric layer 270 may be a thermal oxidation process. In this embodiment, the forming process of the dielectric layer 270 is a rapid thermal oxidation process, but it is not limited thereto. The method of etching the dielectric layer 270 on the first region A1 may be a wet etching process P3. In this embodiment, the wet etching process P3 is a buffered oxide etch (BOE) process, but it is not limited thereto. This embodiment removes dielectric layer 270 on the first region A1 as an example, but it may remove the dielectric layer 270 on the second region A2 instead.

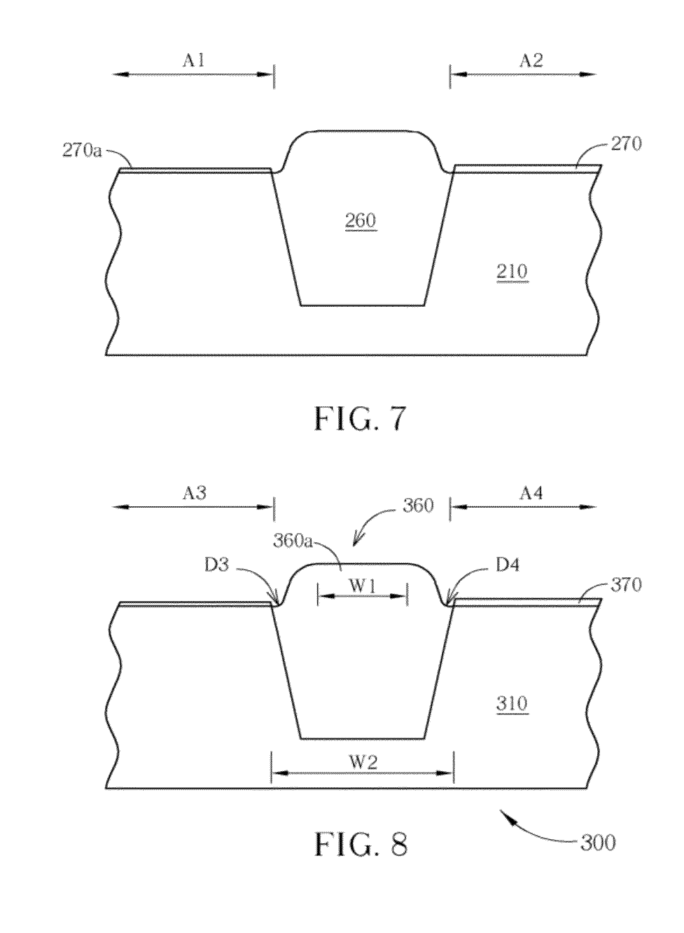

As shown in FIG. 7, a dielectric layer 270a thinner than the dielectric layer 270 is deposited so the manufacturing of different thicknesses of the dielectric layer 270 and 270a is completed. The dielectric layer 270 of the present invention may be a gate dielectric layer, and a gate structure may be further formed thereon. For example, after the wet etching process P3 is performed, a gate electrode layer (not shown) may be formed. Thereafter, a gate electrode layer and a gate dielectric layer are patterned, and a spacer and a source/drain region etc. may be sequentially formed. Otherwise, the numbers of the removed dielectric layer and the isolation structure 260 in this embodiment are just one example applied in the present invention, wherein the numbers of the removed dielectric layer and the isolation structure 260 depend upon practical circumstances.

According to the above, the present invention can form the structure shown in FIG. 8, wherein the semiconductor structure 300 includes a substrate 310, at least an isolation structure 360 and a dielectric layer 370. The isolation structure 360 is located on the substrate 310 and each isolation structure 360 has a top 360a protruding from the substrate 310. The dielectric layer 370 is located on the substrate 310 and exposes the isolation structure 360. Additionally, the isolation structure 360 of the present invention can have a smooth profile of the top 360a as compared to the prior art; that is, the top 360a of the present invention substantially has a trapezoid-shaped profile. Moreover, the top width w1 of the top 360a is 40% larger than the bottom width w2 of the top 360a. The substrate 310 next to the top 360a further includes downward dents D3 and D4, but the size of the downward dents D3 and D4 are extremely small as compared to the prior art, wherein the depth of each downward dent D3 and D4 is not larger than 20 angstroms and the width of each downward dent D3 and D4 is not larger than 90 angstroms.

FIG. 10 schematically depicts a cross-sectional view of a semiconductor structure seen by Transmission Electron Microscopy (TEM) according to one embodiment of the present invention. As shown in FIG. 10, the depth of the downward dent D5 of the semiconductor structure 400 formed by applying the method of the present invention is just 8 angstroms, the width of the downward dent D5 can achieve 67 angstroms, the depth of the downward dent D6 is just 12 angstroms and the width of the downward dent D6 can achieve 63 angstroms.

Above all, the present invention provides a semiconductor process and fabricated structure thereof, which removes oxide layers by performing a dry cleaning process, and then selectively performs a wet cleaning process to further remove the remaining residues after the dry cleaning process. Therefore, the semiconductor structure formed by the present invention has a smooth top profile of the isolation structure as compared to the prior art. As a result, the semiconductor process of the present invention can reduce the size of the downward dent on the substrate, leading to an increase in the top width/bottom width ratio of the top of the substrate . For instance, the top width of the top of the semiconductor structure is 40% larger than the bottom width. Therefore, the present invention can solve the problems of the electrical field concentration and the short circuit caused by divots and downward shifting of the substrate height.

Those skilled in the art will readily observe that numerous modifications and alterations of the device and method may be made while retaining the teachings of the invention.

What is claimed is:

1. A semiconductor process, comprising:
providing a substrate, comprising an isolation structure and an oxide layer, wherein the isolation structure divides the substrate into a first region and a second region, and the oxide layer is located on the surface of the first region and the second region;
performing a dry cleaning process to remove the oxide layer;
forming a dielectric layer on the first region and the second region; and
performing a wet etching process to remove at least one of the dielectric layers on the first region and the second region.

2. The semiconductor process according to claim 1, wherein the dry cleaning process comprising a SiCoNi dry cleaning process.

3. The semiconductor process according to claim 1, wherein the dry cleaning process comprises a nitrogen trifluoride and ammonia containing dry cleaning process.

4. The semiconductor process according to claim 1, further comprising:
after performing the dry cleaning process, performing a wet cleaning process to further remove the oxide layer.

5. The semiconductor process according to claim 4, wherein the wet cleaning process comprises a hydrofluoric acid-containing cleaning process.

6. The semiconductor process according to claim 5, wherein the processing time of the hydrofluoric acid-containing cleaning process is 15 seconds.

7. The semiconductor process according to claim 1, wherein the dielectric layer is formed by a thermal oxidation process.

8. The semiconductor process according to claim 7, wherein the dielectric layer is formed by a rapid thermal oxidation process.

9. The semiconductor process according to claim 1, wherein the wet etching process comprises a buffered oxide etch (BOE) process.

10. The semiconductor process according to claim 1, wherein the oxide layer comprises a pad oxide layer.

11. The semiconductor process according to claim 1, wherein the isolation structure comprises a shallow trench isolation structure or a field oxide layer.

12. The semiconductor process according to claim 11, wherein the shallow trench isolation structure is formed by a high aspect ratio process (HARP).

13. The semiconductor process according to claim 1, wherein the dielectric layer comprises a gate dielectric layer.

14. The semiconductor process according to claim 13, further comprising:
after performing the wet etching process, forming agate electrode layer.

15. The semiconductor process according to claim 4, further comprising:
after performing the wet cleaning process, performing a standard clean 1 (SC1) process.

16. The semiconductor process according to claim 15, further comprising:
after performing the wet cleaning process, performing a standard clean 2 (SC2) process.

17. A semiconductor structure, comprising:
a substrate;
at least an isolation structure located on the substrate, wherein the isolation structure has a trapezoid-shaped profile top protruding from the substrate, wherein the top width of the trapezoid shape profile top is 40% longer than the bottom width of the trapezoid-shaped profile top and the substrate next to the sides of the trapezoid-shaped profile top comprises a downward dent; and
a dielectric layer located on the substrate and exposing the isolation structure.

18. The semiconductor structure according to claim 17, wherein the depth of the downward dent is not higher than 20 angstroms.

19. The semiconductor structure according to claim 17, wherein the width of the downward dent is not higher than 90 angstroms.
